(19) United States
(12) Patent Application Publication
(10) Pub. No.: US 2005/0152115 A1
(43) Pub. Date: Jul. 14, 2005

(54) Thermal module

(76) Inventor: Chui-Kai Peng, Hsin Chu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/753,426

(22) Filed: Jan. 9, 2004

(51) Int. Cl. H05K 7/20

(52) U.S. Cl. 361/703; 361/709

(57) ABSTRACT

The present invention is in related to an improved thermal module, comprising a heat-absorbing portion, a heat-transmitting portion and a heat-conducting portion, a fixing structure fastening the three portions. The heat-absorbing portion absorbs heat generated by a heating element as a chip firstly, and the absorbed heat is then delivered to the heat-conducting portion by means of the heat-transmitting portion for radiation of heat due to a wide surface of the heat-conducting portion. The fixing structure has a piece of flexible member and plural joining elements, the flexible member covers on the heat-absorbing portion as well. An outer rim of the flexible member defines a fastening structure to cooperate with the joining elements for fixing the heat-absorbing portion.

### BACKGROUND OF THE INVENTION

### FIELD OF INVENTION

The present invention relates to an improved thermal module adopted for use on heating elements that generate a smaller amount of heat has a fixing structure for fastening the thermal module to the heating element of an electronic device without hitting the elements or circuits on the circuit board.

With continuous progresses in industries, people's living is more convenient. This is especially true with the widely use of computers and their peripheral devices. Some of those products have overcome technology barriers many people thought insurmountable in the past. Many things people can only dream of just a few years ago now have been realized. These products have gradually woven into people's life and become indispensable now.

Chip such as CPU is one of the most important products in the modern technology era. It can process very complicated programs not possible by human being. These days almost all computers and their peripheral devices have chips mounted onto their circuit boards. Chip generates heat during processing. How to resolve heat dissipation for chips has become one of the critical problems many vendors encounter.

In the earlier time, heat generation by chips during processing is not very significant. The problems caused by rising temperature were not very severe then. Hence installing radiating device on the chip was rare. For instance, the VGA cards of the earlier versions did not generate much heat. They could function well without any facility to disperse heat into the air. For some chips that generate a greater amount of heat, they are attached with radiation fins to increase the heat dissipation surface area.

With increasing advances of the industries, the processing speed of the chip become faster. Consequently heat being generated during operation increases significantly. The earlier technique of dispersing heat through contact with air can no longer meet requirements. Some vendors have installed fan on the chip or radiation fins. The fan generates airflow to create convection to rapidly carry away the heat on the chip or transferred to the radiation fins. Such an approach can prevent heat from accumulating on the chip to avoid the temperature from rising too high and burning out the chip. While the fan can create convection and forcefully carry the heat away from the chip, it also creates additional problems, notably:
1. The fan requires electricity to operate to generate airflow and convection. It needs additional electric power. Moreover, during fan operation, electromagnetic interfering (EMI) occurs. This affects chip operation. The processing speed of the chip could slow down or errors might occur.
2. The fan has to be operated immediately when the chip processes to dispel the heat generated by the chip. Hence as long as the chip is operating, the fan must operate constantly to keep the surrounding temperature of the chip from rising too high. Otherwise the chip might be burned out. The fan tends to gather dusts after having been operated for a period of time. These dusts will affect the rotation speed of the fan. Hence the dusts gathered on the fan have to be cleared periodically to restore the original performance. However, not every user knows how to clear the dusts accumulated on the fan, or does not clear thoroughly. As a result, the rotation spindle of the fan requires a greater power to activate at the initial time. It could result in burn-out of the spindle or the spindle could be jammed and become not operable. If this happened, the possibility of the chip being burned out increases significantly. And the entire device has to be replaced once it happens. This is a big financial burden to consumers.

Some vendors have introduced water cooling systems to carry away heat generated by the chip. While the water cooling systems have desired cooling speed, they are expensive and heavy. They are not convenient for users to carry. Moreover, the water cooling system is more suitable for chips of greater heat generation. They are not desirable for the chips that do not generate much heat.

In addition, the conventional techniques for fastening fan usually employ screws to fasten the fan to the circuit board or radiation fins. Installation or removing could easily hit the elements or circuits on the circuit board. As the fan has to be removed for cleaning frequently, the fastening screws have to be unfastened at the same time. Due to the screws and screw holes on the radiation fins are not always well designed or fully conform to industry standards, the screw threads of the screws and screw holes could be worn out after frequent installation and removing. Some even cannot be fastened again. This creates another concern.

### SUMMARY OF THE INVENTION

Therefore the primary object of the invention is to provide an improved thermal module that employs a heatpipe to achieve heat dissipation effect. Such a design does not have service life limitation, also does not need electricity to transfer heat. And EMI also does not occur.

Another object of the invention is to provide a fixing structure to avoid hitting elements and circuits on the circuit board. The fixing structure uses joining elements that fully conform to industry standards. They may be installed and removed repeatedly without wearing the screw threads.

The invention includes a thermal module and a fixing structure. The thermal module includes a heat-absorbing portion, a heat-transmitting portion and a heat-conducting portion. It is fastened by the fixing structure. When a heating element of an electronic device starts processing and generates heat, the heat is absorbed by the heat-absorbing portion. The heat-transmitting portion transfers the heat to the heat-conducting portion. The heat-conducting portion has a large surface area to disperse the heat to the ambience. The fixing structure has a flexible member and a plurality of joining elements. The flexible member is a thin plate for covering the heat-absorbing portion. The flexible member also has fastening structure on the outer rim to couple with the joining elements to fasten the heat-absorbing portion.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of a first embodiment of the invention.

FIG. 2 is a schematic view of a second embodiment of the invention.

FIG. 3 is a fragmentary schematic view of a third embodiment of the invention.

FIG. 4 is a fragmentary schematic view of a fourth embodiment of the invention.

FIG. 5 is a fragmentary schematic view of a fifth embodiment of the invention.

FIG. 6 is a fragmentary schematic view of a sixth embodiment of the invention.

### DESCRIPTION OF THE PREFERRED EMBODIMENTS

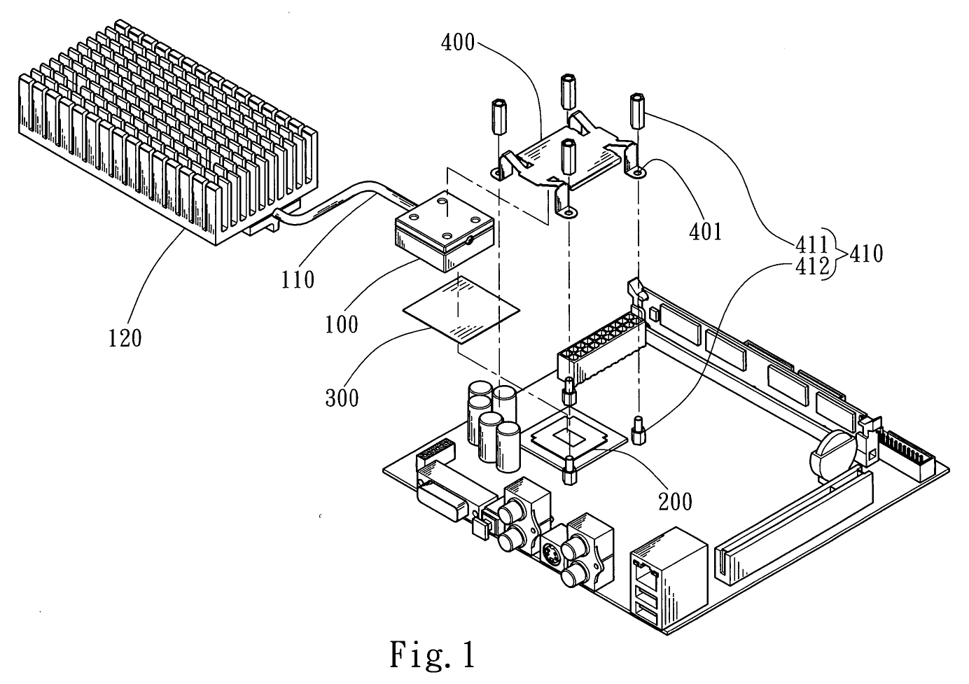

Refer to FIG. 1 for a first embodiment of the invention that includes a thermal module. The thermal module includes a heat-absorbing portion 100, a heat-transmitting portion 110 and a heat-conducting portion 120. They are fastened by a fixing structure. The heat-absorbing portion 100 is abutting a heating element 200 such as a chip to absorb heat generated by the heating element 200 during operation. There is a radiation pad 300 located between the heat-absorbing portion 100 and the heating element 200. The radiation pad 300 has a good thermal conductive coefficient and provides the heat-absorbing portion 100 and the heating element 200 a better contact area. The heat-transmitting portion 110 is a tubular heatpipe with one end embedded in the heat-absorbing portion 100 for carrying heat accumulated in the heat-absorbing portion 100 to other end. The other end is embedded in the heat-conducting portion 120. The heat-conducting portion 120 is located remote from the heat-absorbing portion 100 and the heating element 200, and has a large surface area in contact with the ambience to disperse heat rapidly so that the heat does not accumulate in the device, thereby the temperature of the heating element 200 may be prevented from rising too high and resulting in the risk of burning out. The two ends of the heat-transmitting portion 110 may be coated with a thermal conductive medium such as radiation paste (not shown in the drawings) to reduce the gap between the heat-absorbing portion 100 and the heat-conducting portion 120 and increase heat conductive area.

The fixing structure includes a flexible member 400 and a plurality of joining elements 410. The flexible member 400 is a thin plate formed in π-shape to cover the heat-absorbing portion 100 and has a fastening structure on the outer rim that includes a plurality of fastening holes 401. Each joining element 410 includes a fastening bolt 411 and a nut 412. The fastening bolts 411 are arranged around the heating element and may be inserted into the fastening holes 401 to couple with the nuts 412 for fastening. The flexible member 400 also is in contact tightly with the heat-absorbing portion 100.

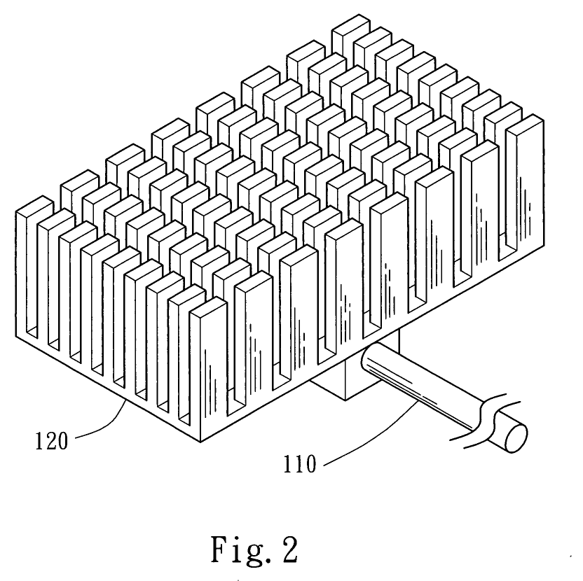

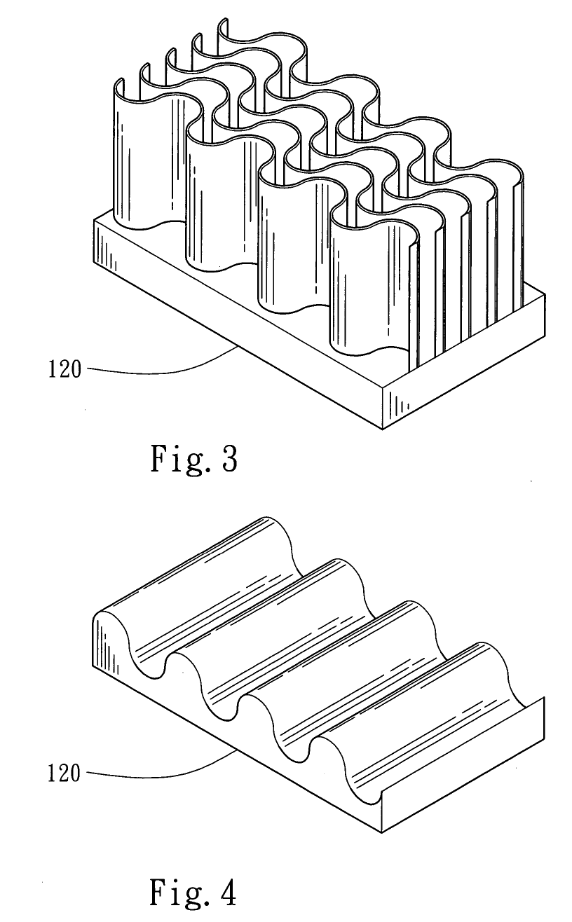

Refer to FIG. 2 for a second embodiment of the invention. The main difference from the previous embodiment is the heat-conducting portion 120. It has the same effect as the previous embodiment. For installation, the heat-conducting portion 120 is turned for 90 degrees to connect to the heat-transmitting portion 110. The heat-conducting portion 120 has a large surface area to increase the heat dissipation area. Refer to FIGS. 3 and 4 for other embodiments of the invention. The heat-conducting portion 120 is formed in an undulate manner and extended from the radiation deck, and the surface of the radiation deck may also be formed in an undulate fashion to increase the heat dissipation area.

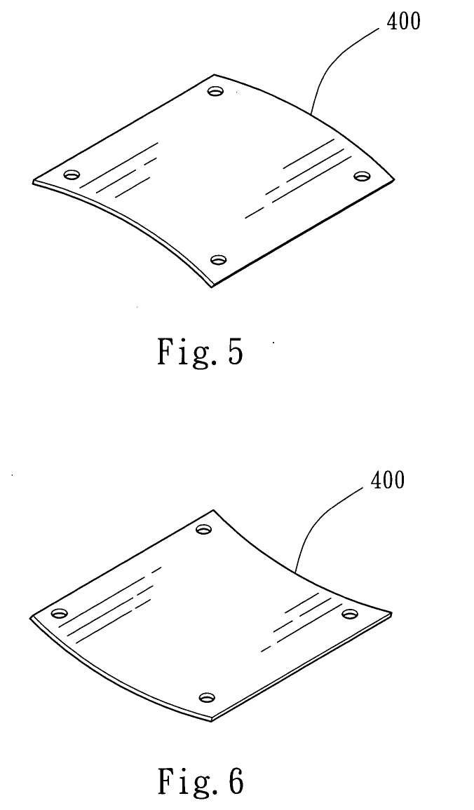

Refer to FIG. 5 for a fourth embodiment of the invention. The main difference from the first embodiment is the flexible member 400. The flexible member 400 in this embodiment is a thin plate formed in a protrusive fashion and functions equally well. It also may be a thin plate formed in an indented manner (referring to FIG. 6). Both of them can be used as the flexible member 400 to fasten the heat-absorbing portion 100 (as shown in FIG. 1).

In summary, the invention provides an improved thermal module that uses a thermal module equipped with a heat pipe to replace the conventional fan. It offers a lot of benefits, such as does not have service life limitation, consumes no electricity, does not creates EMI, and does not harm the circuit board during installation and removing.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

1. An improved thermal module adopted for use on an electronic device that generates a smaller amount of heat, comprising:
a heat-absorbing portion for absorbing the heat generated by the electronic device during operation;
a heat-transmitting portion having one end connecting to the heat-absorbing portion to deliver the heat absorbed by the heat-absorbing portion; and
a heat-conducting portion connecting to another end of the heat-transmitting portion for dispersing the heat delivered from the heat-transmitting portion to ambience.

2. The improved thermal module of claim 1 further having a fixing structure and a plurality of joining elements, the fixing structure including a flexible member which is a thin plate to cover the heat-absorbing portion and has outer rims to form a fastening structure to couple with the joining elements to fasten the heat-absorbing portion.

3. The improved thermal module of claim 1, wherein the electronic device is selected from a group consisting of a video device and a VGA card.

4. The improved thermal module of claim 1, wherein the heat-transmitting portion is a heat pipe.

5. The improved thermal module of claim 1, wherein the heat-conducting portion is a radiation fin that has a large surface area to improve heat dissipation effect.

6. The improved thermal module of claim 5, wherein the radiation fin has a radiation deck which has struts extending outwards.

7. The improved thermal module of claim 5, wherein the radiation fin has a radiation deck which has undulate fins extending outwards.

8. The improved thermal module of claim 2, wherein the fixing structure includes a plurality of fastening holes to fasten to the joining elements by screw coupling.

9. The improved thermal module of claim 2, wherein the flexible member is formed in a cross section selecting from a group consisting of a π-shape, a protrusive shape and an indented shape.

10. An improved thermal module adopted for use on an electronic device that generates a smaller amount of heat, comprising:
a heat-absorbing portion for absorbing the heat generated by the electronic device during operation;
a heat-transmitting portion having one end connecting to the heat-absorbing portion to deliver the heat absorbed by the heat-absorbing portion;
a heat-conducting portion connecting to another end of the heat-transmitting portion for dispersing the heat delivered from the heat-transmitting portion to ambience; and
a fixing structure which includes a flexible member and a plurality of joining elements, the flexible member being a thin plate to cover the heat-absorbing portion and has outer rims to form a fastening structure to couple with the joining elements to fasten the heat-absorbing portion.

11. The improved thermal module of claim 10, wherein the electronic device is selected from a group consisting of a video device and a VGA card.

12. The improved thermal module of claim 10, wherein the heat-transmitting portion is a heatpipe.

13. The improved thermal module of claim 10, wherein the heat-conducting portion is a radiation fin that has a large surface area to improve heat dissipation effect.

14. The improved thermal module of claim 13, wherein the radiation fin has a radiation deck which has struts extending outwards.

15. The improved thermal module of claim 13, wherein the radiation fin has a radiation deck which has undulate fins extending outwards.

16. The improved thermal module of claim 10, wherein the fastening structure includes a plurality of fastening holes to fasten to the joining elements by screw coupling.

17. The improved thermal module of claim 10, wherein the flexible member is formed in a cross section selecting from a group consisting of a π-shape, a protrusive shape and an indented shape.
